(19) United States
(12) Patent Application Publication
(10) Pub. No.: US 2019/0249306 A1
(43) Pub. Date: Aug. 15, 2019

(54) APPARATUS AND METHODS FOR REDUCING CROSS-CONTAMINATION IN CVD SYSTEMS

(71) Applicant: Applied Materials, Inc., Santa Clara, CA (US)

(72) Inventors: Shuran SHENG, Saratoga, CA (US); Chang Hee SHIN, Milpitas, CA (US)

(21) Appl. No.: 16/259,285

(22) Filed: Jan. 28, 2019

Related U.S. Application Data
(60) Provisional application No. 62/628,854, filed on Feb. 9, 2018.

(51) Int. Cl. C23C 16/54; C23C 16/44; H01L 31/18; H01L 31/0384

(52) U.S. Cl. CPC C23C 16/54; C23C 16/4404; H01L 31/075; H01L 31/0384; H01L 31/18

(57) ABSTRACT

Apparatus and methods are provided for reducing cross-contamination between deposition operations during the fabrication of heterojunction cells. An apparatus includes the substrate carrier including a plurality of pockets, and the carrier mask defining the openings that are sized and positioned in correspondence to the pockets of the substrate carrier. The substrate carrier carries a plurality of substrates into an i-layer deposition chamber and a p-layer deposition chamber. The substrate carrier is masked by the carrier mask during deposition of a p-layer. In-situ film mask layer can be used with or without the carrier mask. The in-situ film mask layer is formed of SiN or SiNO and can be deposited over the p-layer. The p-layer is a p-type nanocrystalline SiOx layer formed from a combination of SiH4, B2H6, H2 or CO2. A single substrate carrier can be repeatedly used for sequential deposition of an i-layer and a p-layer without cross contamination.

### CROSS-REFERENCE TO RELATED APPLICATIONS

This application claims benefit of U.S. provisional patent application Ser. No. 62/628,854, filed Feb. 9, 2018, which is herein incorporated by reference.

### BACKGROUND

### Field

The present disclosure relates to apparatus and methods for eliminating or reducing cross-contamination during fabrication processes in chemical vapor deposition (CVD) systems. In particular, the present disclosure provides a carrier mask for masking the surface of a substrate carrier during a p-type boron doped silicon (p-layer) deposition process. The present disclosure also provides methods for eliminating or reducing cross-contamination during the fabrication of heterojunction cells or semiconductor devices by using a substrate carrier mask, so that a single substrate carrier can be used for the sequential deposition of an intrinsic layer (i-layer) and a p-layer.

### Description of the Related Art

A silicon (Si) heterojunction cell has a relatively high solar energy conversion efficiency, which requires uniform deposition of amorphous silicon (a-Si) and silicon dielectric thin films. Silicon heterojunction cells can be fabricated by high volume manufacturing (HVM) plasma-enhanced chemical vapor deposition (PECVD).

During the PECVD fabrication process of a heterojunction cell for example, cross-contamination may occur between deposition of an i-layer and a p-layer due to prior boron-doped p-layer coatings remaining on the substrate carrier. The boron-doped p-layer material that remains on the carrier can result in contamination of a subsequent layer. Contamination of the subsequent layer can negatively affect the intrinsic layer passivation performance of the device. To prevent cross-contamination, dedicated substrate carriers can be used for deposition of both the i-layer and the p-layer. However, using dedicated substrate carriers for each deposition process requires that the substrates be exchanged between carriers, and/or that a larger number of processing systems be used. These factors make the fabrication process more complicated, thus lowering the throughput and increasing the capital expenditure.

Therefore, there is a need for procedures for eliminating or reducing carrier cross-contamination while fabricating heterojunction cells in CVD systems. Eliminating or reducing carrier cross-contamination can lead to benefits such as increased throughput and reduced capital expenditure while retaining device performance characteristics because a need for dedicated substrate carriers is reduced or eliminated. For example, the need for dedicated substrate carriers throughout sequential depositions of an i-layer and a p-layer within the same processing system is reduced or eliminated.

### SUMMARY

Implementations of the present disclosure generally relate to apparatus and methods for eliminating or reducing cross-contamination in the fabrication of heterojunction cells or other electronic devices in CVD systems.

In one aspect, an apparatus for fabricating a heterojunction cell includes a substrate carrier having a plurality of pockets formed thereon that are configured to carry a plurality of substrates and a carrier mask to be placed on the substrate carrier during deposition. The carrier mask includes a frame defining a plurality of openings that are sized and positioned in correspondence to the pockets of the substrate carrier. The openings of the mask can be sized smaller than the size of the pockets.

In another aspect, a carrier mask for fabricating a heterojunction cell has a plurality of octagonal openings, wherein the octagonal openings have sides and corners that are shorter in length than a length of the sides. The carrier mask is configured to cover outer regions of pockets of a substrate carrier during deposition of different layers on the substrates. The substrate carrier may have octagonal pockets that are similar to the octagonal openings.

In another aspect, a method for fabricating a heterojunction cell includes positioning a plurality of substrates into respective pockets formed on a first substrate carrier; depositing an intrinsic layer (i-layer) on the substrates carried on the first substrate carrier; placing a carrier mask on the first substrate carrier carrying the substrates thereon; and depositing a p-type boron doped layer (p-layer) on the substrates carried on the first substrate carrier.

In one implementation, the method further includes, before positioning the substrates into the plurality of pockets of the first substrate carrier: positioning the plurality of substrates into a plurality of pockets on a second substrate carrier; depositing the i-layer on the substrates carried on the second substrate carrier; depositing an n-type doped layer (n-layer) on the i-layer of the substrates carried on the second substrate carrier; and flipping over the substrates for further processing.

In another implementation, the first substrate carrier and the second substrate carrier are the same.

In yet another implementation, the method further includes attaching a chamber shadow frame to the first substrate carrier, the chamber shadow frame overlying a periphery of the first substrate carrier.

In yet another implementation, the carrier mask is made of an Ni alloy and is coated with Al. Alternatively, the carrier mask is made of carbon-based materials—such as carbon fiber or flexible graphite foils—for good mechanical or thermal properties, superior resistance to fluorine-based radicals or plasma clean, or reduced contamination.

In yet another implementation, the p-layer is formed using a reactive gas mixture of silane (SiH₄), diborane (B₂H₆), and/or hydrogen (H₂), with or without CO₂, and with a small amount of p-type dopant.

In yet another aspect, a non-transitory computer-readable storage medium contains instructions that, when executed, causes a processor to perform operations for fabricating a heterojunction cell, the operations comprising: positioning a plurality of substrates into a plurality of pockets formed on a first substrate carrier; depositing an intrinsic layer (i-layer) on the substrates carried on the first substrate carrier; placing a carrier mask on the first substrate carrier carrying the substrates thereon; and depositing a p-type boron doped layer (p-layer) on the substrates carried on the masked substrate carrier.

In another implementation, the operations further include, before positioning the substrates into the plurality of pockets of the first substrate carrier: positioning the plurality of substrates into a plurality of pockets formed on a second substrate carrier; depositing the i-layer on the substrates carried on the second substrate carrier; depositing an n-type doped layer (n-layer) on the i-layer of the substrates carried on the second substrate carrier; and flipping over the substrates for further processing.

### BRIEF DESCRIPTION OF THE DRAWINGS

So that the manner in which the above recited features of the disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1A illustrates an exemplary carrier mask 120 to mask a surface bordering the pockets of a substrate carrier 110 in accordance with one aspect of the present disclosure.

FIG. 1B is a magnified view of a portion circled in FIG. 1A.

FIG. 1C is a cross-sectional view taken along section line 10-10 in FIG. 1B.

FIG. 1D is a cross-sectional view taken along section line 1D-1D in FIG. 1B.

FIG. 1E is a plan view illustrating an exemplary in-situ carrier mask 130 in accordance with one aspect of the present disclosure.

FIG. 2A is an exemplary flowchart illustrating a fabrication process of a heterojunction cell in accordance with one aspect of the present disclosure.

FIGS. 2B1 and 2B2 illustrate exemplary cross-sectional views of a substrate positioned on a carrier at each step of the fabrication process in accordance with one aspect of the present disclosure.

FIG. 2C is a cross-sectional view illustrating an exemplary substrate with a p-layer formed thereon in accordance with one aspect of the present disclosure.

FIG. 2D is a cross-sectional view illustrating another exemplary substrate with a p-layer formed thereon in accordance with one aspect of the present disclosure.

FIG. 3 is a cross-sectional view of an exemplary heterojunction cell which is manufactured according to the fabrication process described in the present disclosure.

FIG. 4 illustrates exemplary cluster systems for fabricating a heterojunction cell using a carrier mask in accordance with one aspect of the present disclosure.

To facilitate understanding, identical reference numerals have been used, where possible, to designate identical elements that are common to the figures. It is contemplated that elements disclosed in one implementation may be beneficially utilized on other implementations without specific recitation.

### DETAILED DESCRIPTION

The present disclosure relates to apparatus and methods for eliminating or reducing cross-contamination during the fabrication of a heterojunction cell. In one aspect, the present disclosure provides a carrier mask for masking the boundary surface regions outside the pockets of the substrate carrier. The carrier mask can be used, for example, during a p-type amorphous silicon deposition process. The present disclosure also provides methods for fabricating a heterojunction cell by using a substrate carrier and a substrate carrier mask to eliminate or reduce the cross-contamination caused by prior deposition of potentially contaminating layers, such as p-layer coatings on a substrate carrier. The present disclosure also provides a substrate carrier and a carrier mask that can be used in combination so that a single substrate carrier can be used for the sequential deposition of an i-layer and/or a p-layer. The present disclosure further provides methods for fabricating a silicon heterojunction cell by using a carrier mask and substrate carrier.

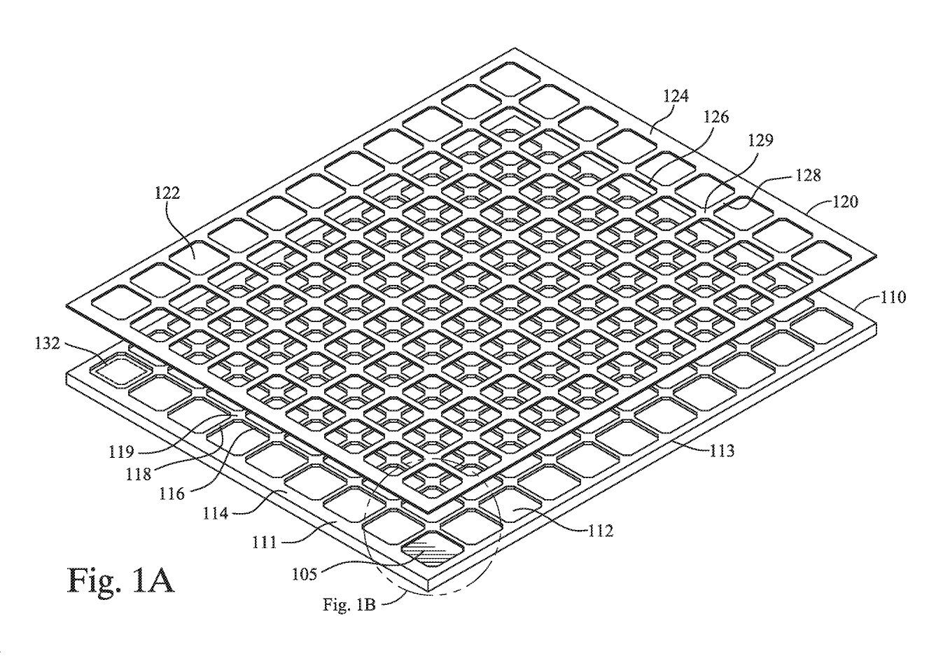

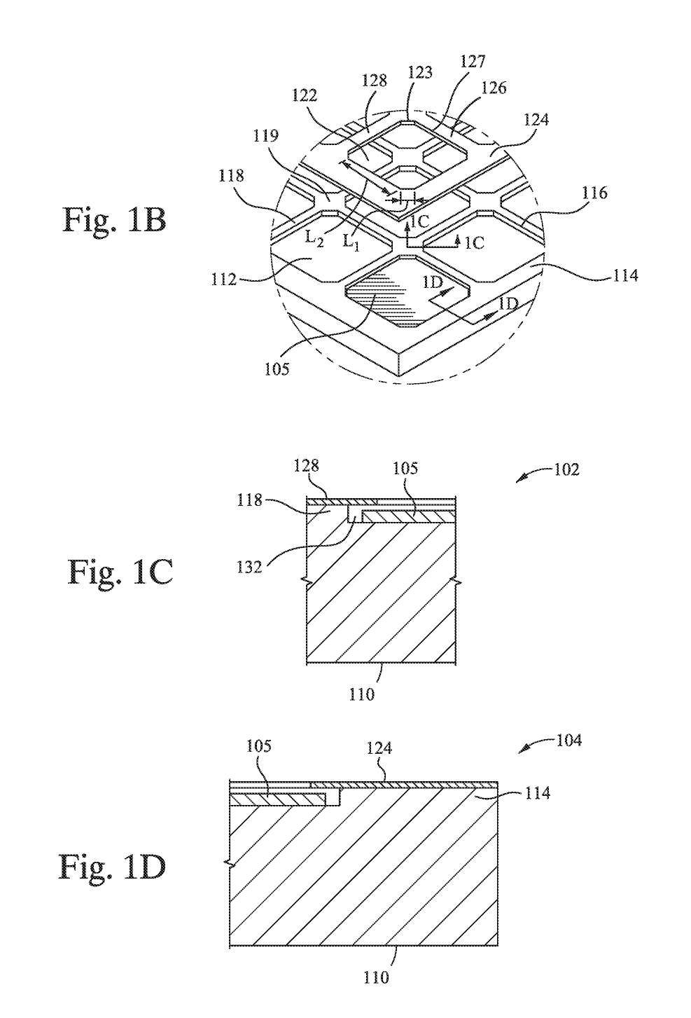

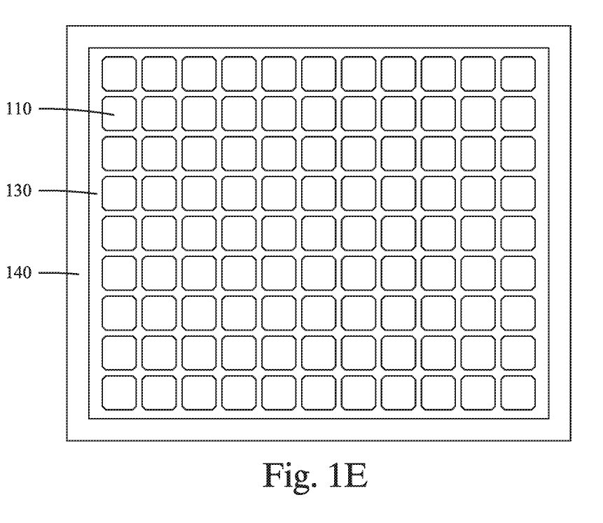

FIG. 1A illustrates an exemplary carrier mask 120 to mask the surface outside the pockets of a substrate carrier 110 in accordance with one aspect of the present disclosure.

The substrate carrier 110 includes a body 114 defining a plurality of pockets 112 on which substrates 105 are placed. The substrate carrier 110 can carry substrates 105 thereon between various chambers according to various fabrication processes.

The plurality of pockets 112 of the substrate carrier 110 may be in any suitable shape and size for carrying substrates 105 in a secure manner. In one or more embodiments, the pockets 112 of the substrate carrier 110 may be in a shape and size suitable to carry substrates thereon. In one or more embodiments, the pockets 112 of the substrate carrier 110 may be in any polygonal, square, rectangular, curved or otherwise non-circular shape. As another example, the pockets 112 of the substrate carrier 110 can have a 5-inch side length, a 6-inch side length, or any other suitable side length to carry substrates.

The carrier mask 120 includes a frame 124 defining a plurality of openings 122 therein. The openings 122 are sized and positioned to correspond to the pockets 112 in the substrate carrier 110. In one or more embodiments, the openings 122 are formed to expose the pockets 112 for a deposition process. In one or more embodiments, the carrier mask 120 has the same length and width as the substrate carrier 110 to assist in alignment, and has a thickness between about 0.5 mm and about 5 mm. When positioned on the substrate carrier, the carrier mask masks the body 114 of the substrate carrier defining the pockets of the substrate carrier 110.

The detailed structures of the substrate carrier 110 and carrier mask 120 are described below with reference to FIGS. 1B, 1C and 1D.

FIG. 1B is a magnified view of the circled portion in FIG. 1A.

Substrate carrier 110 includes a body 114 and pocket dividers 116, 118 formed inside the body 114, defining the plurality of pockets 112. The substrate carrier 110 can support substrates 105 in the pockets 112 for transfer between various chambers according to various fabrication processes.

The plurality of pockets 112 of the substrate carrier 110 may be in any suitable shape and size for carrying substrates 105 in a secure manner. In one or more embodiments, the pockets 112 of the substrate carrier 110 may be in a shape and size suitable to carry substrates thereon. In one or more embodiments, the pockets 112 of the substrate carrier 110 can be in a regular or non-regular octagonal shape as shown in FIG. 1B. In one or more embodiments, the pocket dividers 116, 118 can have a different shape to define a different shape of the pockets 112. For example, when the pockets 112 are in a shape of a square, the pocket dividers comprise a vertical pocket divider 118 and a horizontal pocket divider 116 and intersection areas 119 between the vertical pocket divider 118 and the horizontal pocket divider 116.

In one or more embodiments, the substrate carrier 110 can include aligning protrusions (not shown) extending beyond edges of the substrate carrier to align and fasten a carrier mask. The aligning protrusions can be formed in an L-shape at corners of the carrier mask 120. As the carrier mask 120 is placed inside at least two L-shaped aligning protrusions at two corners, the carrier mask 120 can be aligned and fastened to the substrate carrier 116. Other suitable mechanisms can be utilized to align and fasten the carrier mask 120 to a substrate carrier 116.

The carrier mask 120 includes a frame 124 to land on the body 114 of the substrate carrier 110, and members 126, 128 formed inside the frame 124, defining the plurality openings 122. The openings 122 are sized and positioned to correspond to the pockets 112 in the substrate carrier 110. The members can have different shapes to define the different shapes of the openings. For example, when the openings 122 are in the shape of a square, the members comprise a vertical member 128 and a horizontal member 126 and intersection areas 129 between the vertical member 128 and the horizontal member 126.

The carrier mask 120 prevents material from being deposited on the surface 111 of the substrate carrier 110 during a deposition process by covering at least part of the surface 111 of the substrate carrier 110. The frame 124 of the carrier mask 120 is slightly longer than the body 114 of the substrate carrier 110. Each vertical member 128 of the carrier mask 120 is larger than a vertical pocket divider 118 of the substrate carrier 110; and each horizontal member 126 of the carrier mask 120 is larger than the horizontal pocket divider 116 of the substrate carrier 110. For example, in one or more embodiments, the vertical member 128 of the carrier mask 120 is wider than the vertical pocket divider 118 of the substrate carrier in a range from about 0.01 mm to about 1.0 mm. In one or more embodiments, the horizontal member 126 of the carrier mask 120 is wider than the horizontal pocket divider 116 of the substrate carrier 110 in a range, for example, from about 0.01 mm to about 1.0 mm.

Because of minimal thickness of the frame 124 and members of the substrate mask in comparison to the body and dividers of the substrate carrier 110, the sizes of openings 122 of the carrier mask 120 become smaller than the sizes of substrates 105, and only the substrates 105 are exposed during deposition, e.g., deposition of a p-layer. For example, the width or perimeter of an opening 122 can be from about 0.02 mm to about 2.0 mm smaller than the width or perimeter of a substrate 105. In another example, the width or perimeter of an opening 122 can be about 1.0 mm smaller than the width or perimeter of a substrate 105. In one or more embodiments, a size of the openings 122 of the carrier mask 120 is smaller than a size of the pockets 112 of the substrate carrier 110. In one or more embodiments, the carrier mask 120 is configured to cover outer regions 132 of the pockets 112 during deposition of different layers on the substrates 105.

The openings 122 of the carrier mask 120 can be a regular or non-regular octagonal shape. The openings 122 are sized, shaped, and positioned in correspondence to the pockets 112 of the substrate carrier 110. The openings 122 illustrated in FIG. 1B have an octagonal shape. The openings 122 have four corners 123 and four sides 127. A length L₁ of the corners 123 is shorter than a length L₂ of the sides 127.

By using openings 122 that are smaller than pockets 112, or by covering at least part of the surface 111 of the substrate carrier 110 with a carrier mask 120, cross-contamination is reduced or eliminated throughout PECVD processes. Cross-contamination is also reduced or eliminated by using members 126, 128 that are wider than pocket dividers 116, 118.

The carrier mask 120 can be made of Ni or aluminum nickel (AlNi) alloys with an aluminum (Al) coating thereon, or made of carbon-based materials, such as carbon fiber or flexible graphite foils, for good mechanical or thermal properties, superior resistance to fluorine based radicals or plasma clean, or reduced contamination. Other suitable materials can be used which are compatible with layers being deposited and do not result in metal contamination of the layers. The carrier mask 120 also has properties which enable the mask to be cleaned using a dry cleaning process, such as a nitrogen trifluoride (NF₃) remote plasma clean process.

The substrate may be any substrate capable of having material deposited thereon, such as a silicon substrate, for example silicon (doped or undoped), crystalline silicon, silicon oxide, doped or undoped polysilicon, or the like, a germanium substrate, a silicon germanium (Site) substrate, a III-V compound substrate, such as a gallium arsenide substrate, a silicon carbide (SiC) substrate, a patterned or non-patterned semiconductor-on-insulator (SOI) substrate, a carbon doped oxide, a silicon nitride, a solar array, solar panel, a light emitting diode (LED) substrate, or any other materials such as metals, metal alloys, and other conductive materials. The substrate is not limited to any particular size or shape.

FIG. 1C is a cross-sectional view 102 taken along section line 1C-1C in FIG. 1B. As illustrated, the vertical member 128 of the carrier mask 120 is wider than the width of the vertical pocket divider 118 of the substrate carrier 110 in a range, for example, from about 0.01 mm to about 1.0 mm.

FIG. 1D is a cross-sectional view 104 taken along section line 1D-1D in FIG. 1B. As illustrated, the frame 124 of the carrier mask 120 is thin to minimize any shadowing effect.

FIG. 1E illustrates an exemplary in-situ carrier mask 130 in accordance with one aspect of the present disclosure. The in-situ carrier mask 130 can be attached to or integrated with a chamber shadow frame 140 that overlies a periphery 113 (shown in FIG. 1A) of the substrate carrier 110 to prevent deposition on the edge and backside of the substrate carrier 110. In-situ carrier mask 130 stays inside a p-layer deposition chamber.

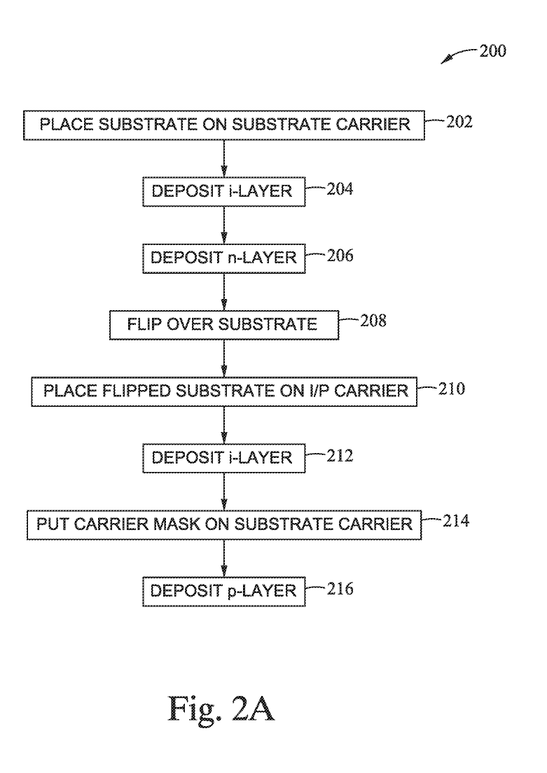

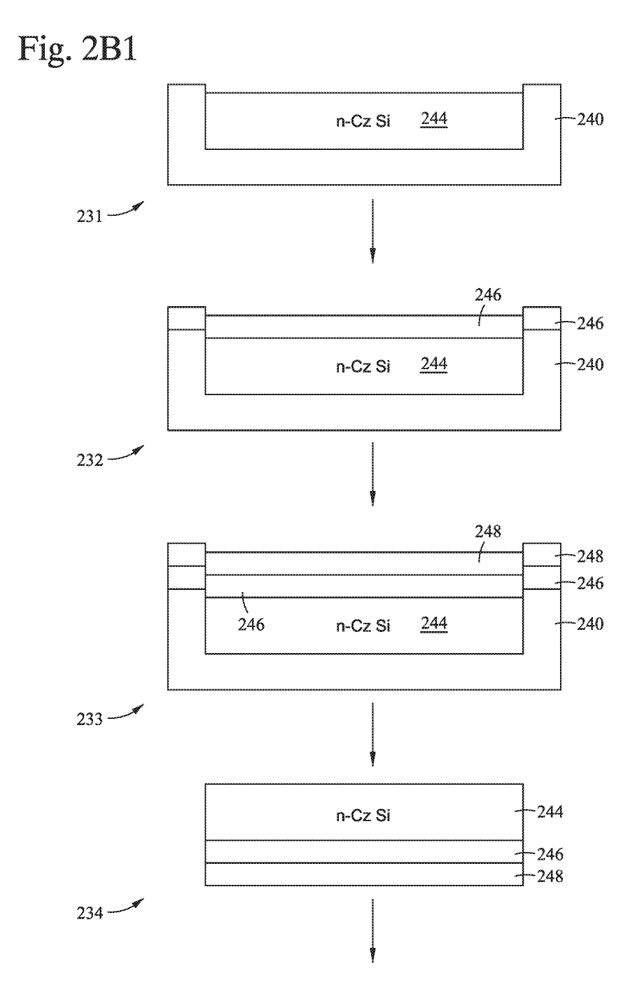

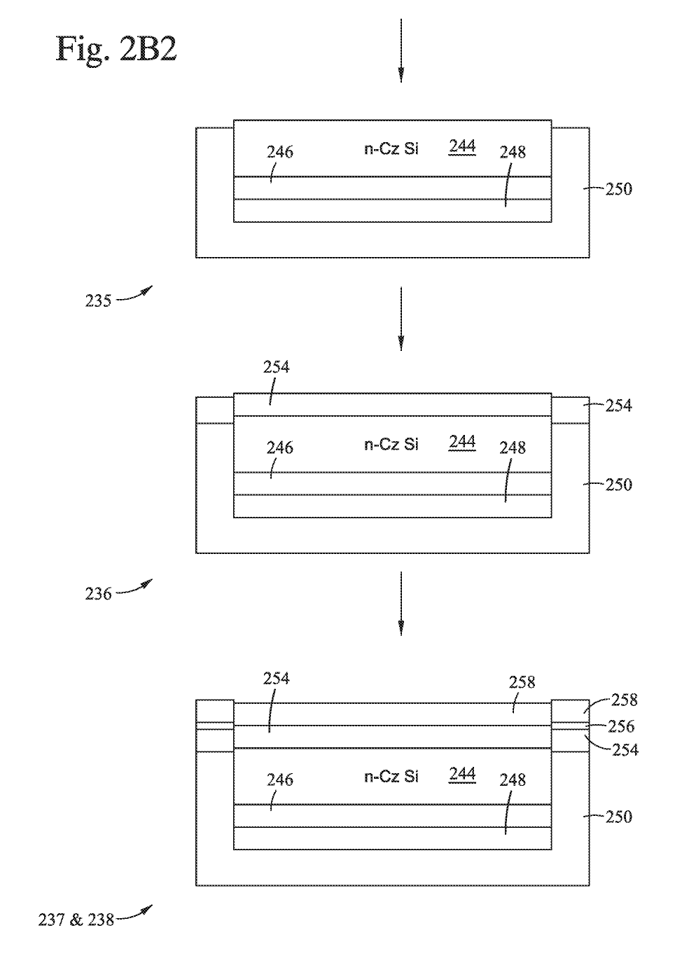

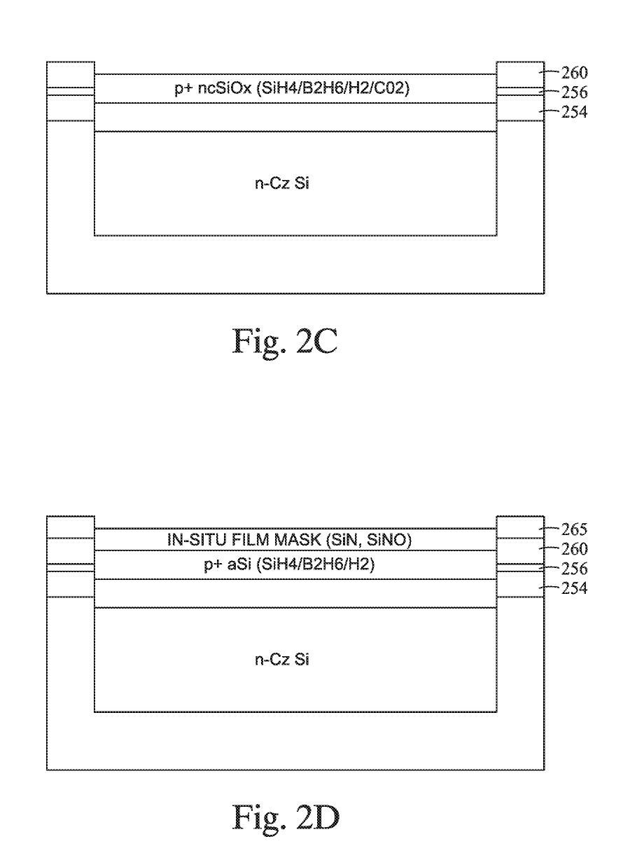

FIG. 2A is an exemplary flowchart 200 illustrating the process of fabricating a heterojunction cell in accordance with one aspect of the present disclosure.

In step 202, the process places a plurality of n-type crystalline silicon substrates into pockets of a substrate carrier.

In step 204, the substrate carrier carrying the substrates thereon is transferred into an i-layer chamber where an amorphous-Si (a-Si) i-layer is deposited over the n-type substrate.

In step 206, after the deposition of the i-layer is complete, the substrate carrier carrying the substrates thereon is transferred into an n-layer chamber where an a-Si n-layer is deposited over the i-layer of the substrate.

In step 208, the substrate carrier carrying the substrates thereon is returned to the loading station where the substrates are taken out of the substrate carrier. Then, the substrates are flipped over and positioned in respective pockets of a substrate carrier which is used for carrying the substrates for the sequential deposition of an i-layer and a p-layer in step 210.

In step 212, the substrate carrier carrying the flipped substrates thereon is transferred into an i-layer deposition chamber where an a-Si i-layer is deposited over the exposed surface of the substrates.

In step 214, a carrier mask is placed on and fastened to the substrate carrier carrying the substrates in a p-layer deposition chamber. In one or more embodiments, the substrate carrier can have L-shaped aligning protrusions extending beyond an edge of the substrate carrier at each corner. The carrier mask is aligned and fastened to the substrate carrier by being placed inside the L-shaped aligning protrusions at corners of the substrate carrier. Other suitable mechanisms can be utilized to align and fasten the carrier mask to a substrate carrier.

In step 216, an amorphous Si p-layer is deposited over the i-layer of the substrates. Thus, the substrate carrier carries a plurality of substrates thereon into an i-layer deposition chamber and a p-layer deposition chamber. The substrate carrier is masked by the carrier mask during deposition of a p-layer. Thus, a single substrate carrier herein can be repeatedly used for sequential deposition of an i-layer and a p-layer without cross contamination. This configuration leads to benefits such as increased throughput, reduced operating costs, and reduced capital expenditures while retaining device performance characteristics. Subsequently, the substrates can be moved to other processing chambers for subsequent processes, such as forming transparent conductive oxide layers and printing a front electrode and a back electrode.

FIGS. 2B1 and 2B2 illustrate exemplary cross-sectional views of a substrate positioned on a substrate carrier at each step of the fabrication process set forth in accordance with one aspect of the present disclosure.

In step 231, a plurality of n-type crystalline silicon substrates 244 are placed into pockets of a substrate carrier 240.

In step 232, the substrate carrier 240 carrying the substrates thereon is transferred into an i-layer chamber where an amorphous-Si (a-Si) i-layer 246 is deposited over the n-type substrate 244.

In step 233, the substrate carrier 240 carrying the substrates 244 thereon is transferred into an n-layer chamber where an a-Si n-layer 248 is deposited over the i-layer 246 of the substrate 244. The result is the formation of a heterojunction structure between the n-type crystalline silicon substrate 244 and the a-Si n-layer 248. The a-Si i-layer 246 provides interface passivation on the n-type crystalline silicon surface. The a-Si i-layer 246 and the a-Si n-layer 248 together provide interface passivation by the i-layer and heterojunction passivation by the n-layer.

In step 234, the substrate carrier 240 carrying the substrates 244 thereon is returned to the loading station where the substrates 244 are taken out of the substrate carrier 240 and flipped over. In step 235, the flipped substrates 244 are positioned in respective pockets of substrate carrier 250 which is used for carrying the substrates 244 for the sequential deposition of an i-layer and a p-layer in step 235.

In step 236, the substrate carrier 250 carrying the flipped substrates thereon is transferred into an i-layer deposition chamber where an a-Si i-layer 254 is deposited on the exposed surface of the substrates.

In step 237, a carrier mask 256 is placed over the substrate carrier 250 carrying the flipped substrates in a p-layer deposition chamber. In one or more embodiments, the substrate carrier 250 can have L-shaped aligning protrusions extending beyond an edge of the substrate carrier at each corner. The carrier mask is aligned and fastened to the substrate carrier by being placed inside the L-shaped aligning protrusions at corners of the substrate carrier 250. In one or more embodiments, the substrate carrier 240 and the substrate carrier 250 are the same, or are different from each other.

In step 238, an a-Si p-layer 258 is deposited over the i-layer 254. In one or more embodiments, the p-layer 258 can be formed using a reactive gas mixture of silane (SiH₄), diborane (B₂H₆) and/or hydrogen (H₂) with a relatively small amount of p-type dopant in a chemical vapor deposition (CVD) chamber. The process sequence performed on the substrates forms an emitter between the n-type crystalline silicon substrate 244 and the a-Si p-layer 258.

FIG. 2C is a cross-sectional view illustrating an exemplary substrate with a p-layer deposited thereon in accordance with one aspect of the present disclosure.

As described above, the p-layer 258 in FIG. 2B2 can be formed of a combination of silane (SiH₄), diborane (B₂H₆) and/or hydrogen (H₂). To make the boron dopant within the p-layer less mobilized, carbon dioxide (CO₂) gas can also be added during the p-layer deposition process. As a result, a p-type nanocrystalline (nc) SiOx layer 260 is formed of a combination of SiH₄, B₂H₆, H₂ and/or CO₂.

The CO₂ addition during p-layer growth can incorporate carbon (C) and oxygen (O) atoms in a manner to reduce or eliminate boron cross-contamination as described in detail as follows. Boron (B) doping efficiency in p-layer is very low, because usually less than 1% B atoms are incorporated on substitutional sites as fourfold coordinated. The vast majority of B atoms in a p-layer are not electronically active, and are either threefold coordinated in Si₂BH or Si₃B configurations, H-passivated Si₃BH, or B—H complexes (B—H—Si, B—Si—H—Si, etc). The B atoms in these bonding configurations will become much less mobile when bonded with O atoms. So, more incorporated O (than C) atoms can make the B atoms in the new p-type SiOx layer become more difficult to diffuse, desorb or release during subsequent i-layer depositions, hence less B cross-contamination. Moreover, the incorporated C atoms can also improve the p-layer thermal stability, and reduce B cross-contamination, as B-containing bonds' dissociation energies is increased by carbon incorporation or bonding. This may be similar to the fact that the doping gas precursor TMB (B(CH₃)₃) is superior to B₂H₆ regarding higher thermal stability and less B cross-contamination.

In addition, the resultant oxidized surface due to the CO₂ addition may promote or facilitate growing a nano-crystalline or micro-crystalline p-layer with a higher doping efficiency and much improved conductivity, compared with the conventional amorphous p-layer.

In one implementation depicted in FIG. 2C, the CO₂ gas addition can be utilized in combination with the carrier mask 256 covering the substrate carrier 240 for deposition of the p-layer thereon. In one or more embodiments, the CO₂ gas addition can be utilized for deposition of the p-layer without using the carrier mask 256.

FIG. 2D is a cross-sectional view illustrating another exemplary substrate with a p-layer formed thereon in accordance with another aspect of the present disclosure.

As illustrated, an in-situ film mask layer 265 formed of silicon nitride (SiN) or silicon oxynitride (SiNO) is deposited over the p-layer 260. The in-situ film mask layer 265 functions as a boron diffusion barrier, reducing the boron cross-contamination. The in-situ film mask layer can be etched off before a subsequent process, if necessary. The in-situ film mask layer 265 can be used with or without the carrier mask.

In one or more embodiments, the in-situ film mask layer can be utilized in combination with the substrate carrier 240 and the carrier mask 256 for deposition of the p-layer thereon. In one or more embodiments, the in-situ film mask layer can be utilized for deposition of the p-layer without using the carrier mask 256.

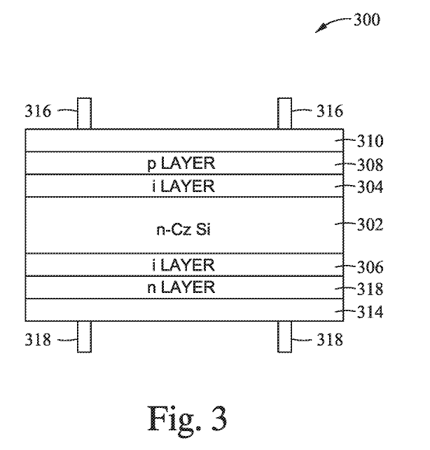

FIG. 3 is a cross-sectional view of an exemplary silicon heterojunction cell 300 fabricated using the methods and apparatus described herein in accordance with one aspect of the present disclosure.

The silicon heterojunction cell 300 includes an n-type crystalline silicon substrate 302 and i-layers 304, 306 deposited over respective opposed sides of the substrate 302. An n-layer 318 is deposited over the i-layer 306, and a p-layer 308 is deposited over the i-layer 304. Then, transparent conductive oxide layer 310, 314 are formed over the p-layer 308 and the n-layer 318, respectively. Front electrode 316 is formed on transparent conductive oxide layer 310 and back electrode 318 is formed on transparent conductive oxide layer 314. Front electrode 316 and back electrode 318 are connected to an energy storage (e.g., a battery) to store electricity produced from the heterojunction cell 300.

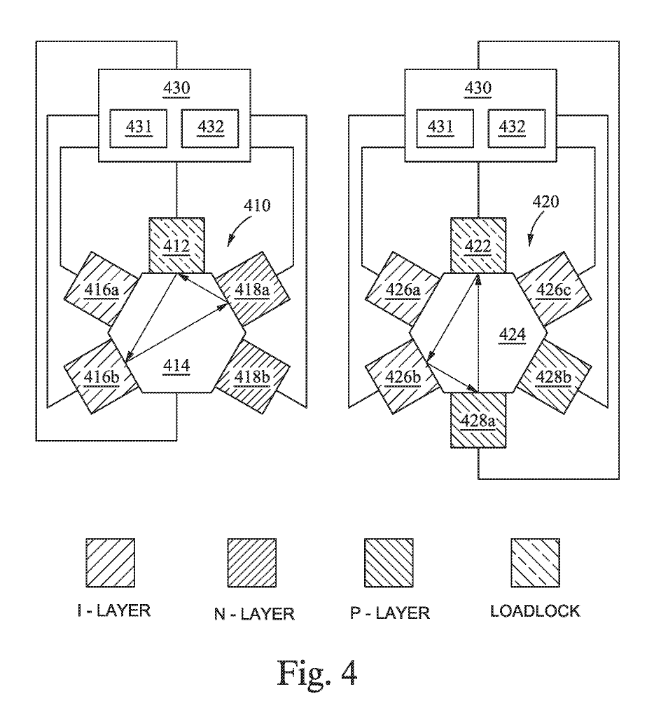

FIG. 4 illustrates exemplary processing systems 410, 420 for fabricating a heterojunction cell in accordance with one aspect of the present disclosure. The processing system 410 includes i-layer deposition chambers 416a-b, n-layer chambers 418a-b, a transfer chamber 414 and a load station 412. Transfer chamber 414 is equipped with a robot adapted to shuttle substrates between the i/n layer deposition chambers 416a-b, 418a-b and the load station 412. The processing system 420 includes i-layer deposition chambers 426a-c, p-layer chambers 428a-b, a transfer chamber 424 and a load station 422.

The exemplary processing systems 410, 420 can include chemical vapor deposition (CVD) chambers such as AKT® PECVD chambers, PRODUCER™ chambers, and PRECISION 5000® chambers commercially available from Applied Materials Inc., Santa Clara, Calif.

The processing systems 410, 420 include a controller 430 programmed to carry out the various processing methods using a substrate carrier and its carrier mask, performed in the cluster systems. The controller includes a programmable central processing unit (CPU) 431 that is operable with a memory 432. The memory 432 is in the form of computer-readable storage media that contains instructions, that when executed by the CPU 431, facilitates the operation of the processing systems 410, 420. The instructions in the memory 432 are in the form of a program product such as a program that implements the methods described in the present disclosure.

The following is an exemplary process sequence for fabricating a heterojunction cell, using the exemplary processing systems 410, 420 in accordance with one aspect of the present disclosure.

A plurality of substrates are placed into pockets of a first substrate carrier within a load station 412. The substrate carrier is then moved into the transfer chamber 414 and then into an i-layer chamber 416b for the deposition of an i-layer thereon.

Once the i-layer deposition process is complete in i-layer chamber 416b, the first substrate carrier is transferred into n-layer chamber 418a, where an n-layer is deposited over the substrates.

Once the n-layer deposition process is complete, the first substrate carrier is moved to a position in the system where the substrates are taken out from the first substrate carrier and are flipped over. The flipped substrates are then positioned on a second substrate carrier. The second substrate carrier can be the same as the first substrate carrier, or can be another substrate carrier different from the first substrate.

The second substrate carrier carrying the flipped substrates is moved into an i-layer chamber 426b of the processing system 420 for deposition of an i-layer thereon. When the i-layer deposition process is complete at the i-layer chamber 426b, the second substrate carrier is masked by a carrier mask and is moved into a p-layer chamber 428a for deposition of a p-layer thereon.

Once the p-layer deposition process is complete, the substrates are taken out from the second substrate carrier and are moved to other processing chambers for subsequent processes, such as forming transparent conductive oxide layers and printing a front electrode and a back electrode.

As described above, using a carrier mask for masking the surface of a substrate carrier during deposition processes in accordance with one aspect of the present disclosure can eliminate or reduce cross-contamination caused by prior p-layer coatings on a substrate carrier. As a result, the same substrate carrier can be used for the sequential deposition of the i-layers and the p-layers, which allows simpler substrate/carrier automation, a higher throughput, and a lower capital expenditure.

While the foregoing is directed to implementations of the present disclosure, other and further implementations of the disclosure can be devised without departing from the basic scope thereof, and the scope thereof is determined by the claims that follow.

What is claimed is:

1. An apparatus, comprising:
a substrate carrier having a plurality of pockets separated by pocket dividers that are configured to carry a plurality of substrates; and
a carrier mask having a frame to land on the substrate carrier, and members formed inside the frame, the members defining a plurality of openings that are sized and positioned in correspondence to the pockets of the substrate carrier, wherein the carrier mask is configured to cover outer regions of the pockets of the substrate carrier during deposition of different layers on the substrates, and wherein a size of the openings of the carrier mask is smaller than a size of the pockets of the substrate carrier.

2. The apparatus of claim 1, wherein the openings of the carrier mask are octagonal and have corners and sides, wherein the corners are shorter in length than a length of the sides.

3. The apparatus of claim 1, wherein the plurality of openings are non-regular octagonal openings that have sides separated by corners that are shorter in length than a length of the sides.

4. The apparatus of claim 1, wherein the pockets of the substrate carrier are in a shape of a square or rectangle, and the pocket dividers comprise a plurality of horizontal pocket dividers, vertical pocket dividers, and intersection areas between the horizontal pocket dividers and the vertical pocket dividers.

5. The apparatus of claim 1, further comprising a chamber shadow frame that overlies a periphery of the substrate carrier to prevent material from being deposited on an edge or backside of the substrate carrier during a deposition process.

6. The apparatus of claim 5, wherein the openings of the carrier mask are octagonal and have corners and sides, wherein the corners are shorter in length than a length of the sides.

7. The apparatus of claim 5, wherein the pockets of the substrate carrier are in a shape of a square or rectangle, and the pocket dividers comprise a plurality of horizontal pocket dividers, vertical pocket dividers, and intersection areas between the horizontal pocket dividers and the vertical pocket dividers.

8. The apparatus of claim 1, wherein the members formed inside the frame of the carrier mask comprise one or more vertical members and the pocket dividers of the substrate carrier comprise one or more vertical pocket dividers, and wherein each vertical member of the carrier mask is wider than each vertical pocket divider of the substrate carrier.

9. The apparatus of claim 8, wherein each vertical member of the carrier mask is wider than each vertical pocket divider of the substrate carrier in a range from about 0.01 mm to about 1.0 mm.

10. The apparatus of claim 1, wherein the carrier mask is made of Nickel (Ni) alloy with Aluminum (Al) coating thereon.

11. The apparatus of claim 1, wherein the carrier mask is configured to mask surface regions outside the pockets of the substrate carrier during sequential deposition of an intrinsic layer (i-layer) and a p-type boron doped layer (p-layer).

12. A method, comprising:
positioning a plurality of substrates into a plurality of pockets formed on a first substrate carrier, wherein the first substrate carrier includes a body and pocket dividers formed inside the body, the pocket dividers defining the plurality of pockets;
depositing an intrinsic layer (i-layer) on the substrates carried on the first substrate carrier;
placing a carrier mask on the first substrate carrier carrying the substrates thereon, wherein the carrier mask includes a frame to land on the body of the first substrate carrier, and members formed inside the frame, the members defining a plurality of openings that are sized and positioned in correspondence to the pockets of the first substrate carrier; and
depositing a p-type boron doped layer (p-layer) on the substrates carried on the first substrate carrier.

13. The method of claim 12, further comprising, before positioning the substrates into the plurality of pockets of the first substrate carrier:
positioning the plurality of substrates into a plurality of pockets formed on a second substrate carrier;
depositing an i-layer on the substrates carried on the second substrate carrier;
depositing an n-type doped layer (n-layer) on the i-layer of the substrates carried on the second substrate carrier; and then
flipping over the substrates.

14. The method of claim 13, wherein the first substrate carrier and the second substrate carrier are the same.

15. The method of claim 12, further comprising: attaching a chamber shadow frame to the first substrate carrier, the chamber shadow frame overlying a periphery of the first substrate carrier.

16. The method of claim 15, wherein the p-type boron doped layer (p-layer) is a p-type nanocrystalline SiOₓ layer formed using a reactance gas mixture of silane (SiH₄), diborane (B₂H₆), or hydrogen (H₂), and CO₂ with an effective amount of p-type dopant.

17. The method of claim 11, wherein one or more of the plurality of openings of the carrier mask are formed to expose the plurality of pockets of the first substrate carrier for a deposition process, a size of the one or more of the plurality of openings being smaller than a size of a substrate.

18. The method of claim 15, further comprising:
depositing an in-situ film mask layer formed of silicon nitride (SiN) or silicon oxynitride (SiNO) on the p-type boron doped layer (p-layer) of the plurality of substrates.

19. A non-transitory computer-readable storage medium containing instructions that, when executed, causes a processor to perform operations comprising:
positioning a plurality of substrates into a plurality of pockets formed on a first substrate carrier, wherein the first substrate carrier includes a body and pocket dividers, the pocket dividers defining the plurality of pockets;
depositing an intrinsic layer (i-layer) on the substrates carried on the first substrate carrier;
placing a carrier mask on the first substrate carrier carrying the substrates thereon, wherein the carrier mask includes a frame to land on the body of the first substrate carrier, and members formed inside the frame, the members defining a plurality of openings that are sized and positioned in correspondence to the pockets of the first substrate carrier; and
depositing a p-type boron doped layer (p-layer) on the substrates carried on the first substrate carrier.

20. The non-transitory computer-readable storage medium of claim 19, wherein the operations further comprises, before positioning the substrates into the plurality of pockets of the first substrate carrier:
positioning the plurality of substrates into a plurality of pockets formed on a second substrate carrier;
depositing the intrinsic layer (i-layer) on the substrates carried on the second substrate carrier;
depositing an n-type doped layer (n-layer) on the intrinsic layer (i-layer) of the substrates carried on the second substrate carrier; and
flipping over the substrates.
